(19) United States
(12) Patent Application Publication
(10) Pub. No.: US 2006/0090917 A1
(43) Pub. Date: May 4, 2006

(54) Support base with movable mounting pad

(76) Inventors: George T. Lowe, Oceanside, CA (US); Jaison Van Schmelzer, Temecula, CA (US); Patrick S. Connors, Scottsdale, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/980,625

(22) Filed: Nov. 2, 2004

(51) Int. Cl. H02G 3/08; H05K 5/00

(52) U.S. Cl. 174/50

(57) ABSTRACT

An enclosure installation assembly comprises a support base and a mounting pad adapted to be secured to the support base. The support base, having a lower portion slightly larger than its upper portion, is placed in a hole in the ground. Dirt is compacted around the support base to secure the support base in place. The mounting pad is then secured to the support base using a coupling structure that engages the support base and mounting pad so as to allow the mounting pad to move relative to the support base. Alternatively, a first portion of the mounting pad is fixedly attached to the support base. A second portion of the mounting pad engages the first portion so as to allow the second portion to move relative to the support base. Finally, an enclosure is installed on the mounting pad, with fasteners located inside the enclosure. The resulting enclosure is securely and easily installed, accessible for maintenance, and is tamper resistant.

### BACKGROUND OF THE INVENTION

1. Field of the Invention

The invention relates generally to enclosures for securely housing a variety of instruments including electrical systems and electronic controls. In particular, the invention relates to a support base with a movable mounting pad for simple and secure installation of a pedestal as well as access to the field wiring for the pedestal.

2. Description of Related Technology

Enclosures are used by irrigation, plumbing and electrical industry professionals to mount and protect electronic controls as well as backflow prevention devices. For an irrigation system, field wiring for sprinkler valves connect with the electronic controls. These enclosures are often located in an easily accessible, outdoor location. Typically, such electronic controls are located inside a metal box-like structure that securely encloses the controls along with a locking door for access to the electronic controls. Access to the field wiring located below the box-like structure is also desirable to adjust or re-route the wiring. The enclosures are sometimes large enough to house not only the controls, but also other items such as tools.

The enclosures are located above ground, usually placed on either a grassy or a dirt surface. Thus, vandals and thieves are able to easily uproot the enclosure from the ground and damage, steal or abuse the contents of the enclosure. To solve this problem, a concrete slab is formed on the ground, attached to a support base, and the enclosure is then installed on the concrete slab. However, this solution requires that the ground first be prepared and equipment be obtained for the pouring of concrete at the site. Further, the field wiring which connects to the enclosure may be difficult to access once the enclosure is installed to the concrete slab. Alternatively, the concrete slab is preformed for installation at the site, requiring highly precise preforming to fit the particular site and the particular enclosure, and heavy equipment to transfer and install the slab at the site.

In some cases, fiberglass mounts are also used. These fiberglass mounts, while lighter and easier to install, also deteriorate upon exposure to ultraviolet (UV) radiation and are easily tampered with.

The concrete slab or fiberglass mount are typically secured to a support base using bolts or similar attachment means. The bolts securing the mount are located above ground and outside the enclosure, where they are exposed to the elements and easily accessed by vandals.

Thus, there is a need for an enclosure support that provides for a simple, yet secure, installation of the enclosure that is vandal-resistant and allows access to the field wiring located below the enclosure.

### SUMMARY OF THE INVENTION

Disclosed herein is an enclosure mounting assembly, and a method of installing the assembly. The invention provides for a secure installation of the enclosure, which is weather-proof, prevents corrosion, resistant to vandals and thieves, while allowing easy access to the interior of the support base.

In accordance with one aspect of the present invention, a mounting assembly is provided for enclosing and accessing electronics or wires. The mounting assembly comprises a support base having a bottom, a top and a substantially hollow interior, the interior configured to contain at least a portion of the electronics or wires, a mounting pad resting on the top of the support base, the mounting pad having an opening in a substantially flat top surface, and a coupling structure attached to the mounting pad, the coupling structure configured to allow the mounting pad to move between an open position and a closed position relative to the support base, wherein the interior is accessible when the mounting pad is in the open position and is inaccessible when the mounting pad is in the closed position.

In accordance with another aspect of the present invention, an enclosure assembly is provided comprising a support base having a bottom, a top and a hollow interior, a mounting pad resting on the top of the support base, the mounting pad having an opening in a top surface, a coupling structure attached to the mounting pad, and an enclosure having a base mounted on the top surface of the mounting pad, the enclosure having an opening in the base sized so as to surround the opening in the top surface of the mounting pad.

In accordance with another aspect of the present invention, a method of securely installing an enclosure mounting pad on an area of ground that comprises digging a hole in the ground to accommodate a support base therein, inserting the support base in the hole, the support base having a top, a bottom and an interior, placing a mounting pad on top of the support base, the mounting pad having an opening in a top surface, and attaching a coupling structure to the mounting pad so as to access the interior when the mounting pad is tilted relative to the support base.

### BRIEF DESCRIPTION OF THE DRAWINGS

FIG. 1 is a perspective view of a support base for an enclosure according to one embodiment of the invention.

FIG. 2 is a perspective view of a mounting pad for an enclosure for use with the support base of FIG. 1.

FIG. 3 is a partially cut-away view of a secure enclosure support system that includes the support base of FIG. 1 and the mounting pad of FIG. 2.

FIG. 4 is an exploded view of an enclosure support system using the support base of FIG. 1, the mounting pad of FIG. 2, and a coupling structure.

FIG. 5 is a perspective view of a component of the coupling structure which attaches to the support base of FIG. 1.

FIG. 6 is a perspective view of another component of the coupling structure which attaches to the mounting pad of FIG. 2.

FIG. 7 is a perspective view of the support base and mounting pad with the mounting pad in an open position which facilitates access within the support base.

FIG. 8 is a front side view of the support base and the mounting pad from FIG. 7.

FIG. 9 is a side view of the support base and the mounting pad from FIG. 7.

FIG. 10 is an exploded view of a stop assembly that can be used with the support base and mounting pad.

FIG. 11 is a cross-sectional view of the enclosure support system of FIG. 3.

FIG. 12 is a cross-sectional view of the enclosure support system of FIG. 3 with an enclosure attached to a top surface of the mounting pad.

FIG. 13 is a perspective view of another embodiment of the support base and mounting pad having a coupling structure in the form of a hinge.

FIG. 14 is a perspective view of the hinge from FIG. 13.

FIG. 15 is a perspective view of another embodiment of the enclosure support system having a two-piece mounting pad and a support base.

FIG. 16 illustrates another embodiment of a support base for use with a multi-piece mounting pad in a system for supporting and installing enclosures.

FIG. 17 is a perspective view of a first mounting pad portion for use with the support base of FIG. 16.

FIG. 18 is a perspective view of a second mounting pad portion for use with the support base of FIG. 16 and the first mounting pad portion of FIG. 17.

FIG. 19 is an exploded view of an enclosure support system using the support base of FIG. 16, the multi-piece mounting pad of FIGS. 17 and 18, a coupling structure, and an anchor member.

FIG. 20 is a perspective view of an anchor member which attaches the support base of FIG. 16 to the second mounting pad portion of FIG. 18.

FIG. 21 is a perspective view of the support base and multi-piece mounting pad with the first mounting pad portion in an open position which facilitates access within the support base.

FIG. 22 is a front side view of the support base and the multi-piece mounting pad from FIGS. 17 and 18.

FIG. 23 is a side view of the support base and the multi-piece mounting pad from FIGS. 17 and 18.

### DETAILED DESCRIPTION OF THE INVENTION

Reference is now made to the drawings wherein like numerals refer to like parts throughout.

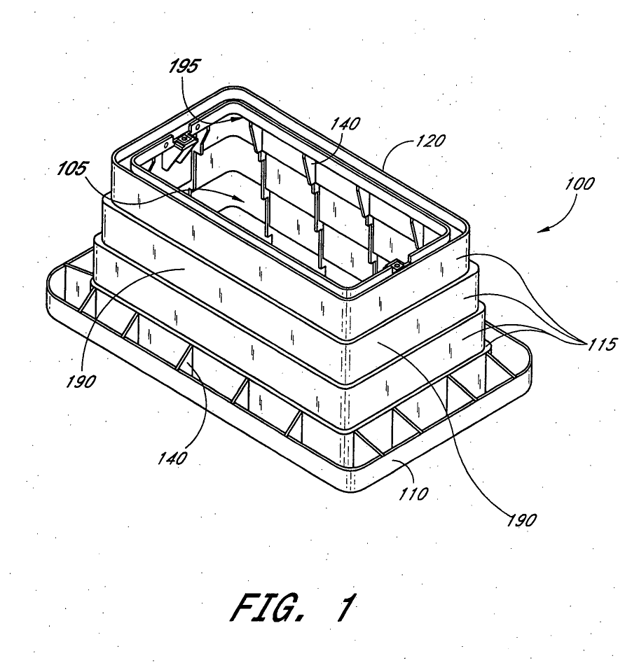

FIG. 1 illustrates one embodiment of a support base 100 for use in a system for supporting and installing enclosures. A preferred support base of the type described below is commercially available from Associated Plastics, Riverside, Calif. As illustrated, the support base 100 is made of several tiers of rectangular-shaped frames 115, stacked upon one another. The size of the frames 115 gradually decreases from bottom to top of the support base 100. The support base 100 is preferably made of a heavy-duty plastic, but may also be formed of fiberglass, metal or any other suitable material. While the support base 100 as illustrated in the figures has several tiers, it is not essential that the support base 100 be so formed. Any support that is larger at its base than at its top and is capable of supporting the weight of the enclosure and mounting pad can be used. It is to be understood that the tiered support is for illustrative purposes only.

The support base 100 preferably has an open bottom (not shown in FIG. 1) and an open top 105 and is hollow throughout. The support base 100 has four side surfaces 190 forming the sides of a rectangular box, and a base 110. The base 110 is the largest of the tiers and forms a relatively large rectangular shape that forms the bottom of the four side surfaces 190 of the rectangular box. The support base 100 is designed to support the mounting pad and the enclosure. Strengthening flanges 140 can be provided at the base 110 to provide additional strength, allowing the support base 100 to support the mounting pad and the enclosure.

As illustrated in FIG. 1, the first frame 115 is located partially above the base 110. The first frame 115 has a rectangular footprint that is smaller than that of the base 110. Thus, the footprint of the first frame 115 is a rectangle located inside another rectangle representing the footprint of the base layer 110. Similarly, a second, third, and fourth frames 115 are provided above the first frame 115, each having a successively smaller rectangular footprint. Each frame 115 has its rectangular footprint within the rectangular footprint of the preceding frame 115. The height of each of the frames may be designed to provide a desired height for the support base 100. The height is selected to provide sufficient stability when the support base 100 is installed. This configuration provides the support base 100 with a somewhat conical profile. According to the embodiment illustrated in FIG. 1, each side surface 190 is provided with three vertical portions 115. However, it is understood that any number of vertical portions 115 can be used to form the side surfaces 190. Alternatively, the side surfaces 190 can be continuous smooth surfaces forming a truncated pyramidal shape. Additionally, it is understood that the support base 100 need not be of a rectangular shape; various shapes can be used, including but not limited to any polygonal cone or a purely circular cone.

Preferably, strengthening flanges 140 are provided on the inside and/or outside surface of the support base 100. The flanges 140 run substantially vertically along the side surfaces 140 of the support base 100. The flanges 140 provide support for the vertical portions 115 of the four side surfaces 190.

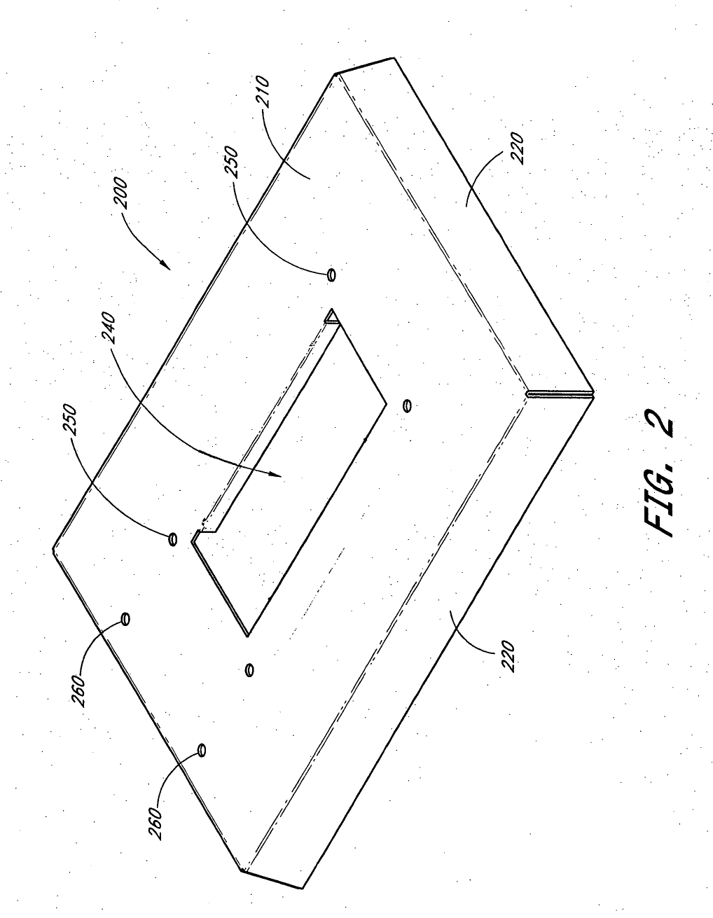

A ledge 195 is located on the interior surface of the support base 100, near the top edge 120. The top edge 120 is preferably of a substantially rectangular shape. The top edge 120 of the uppermost vertical portion 115 serves as a resting surface for a mounting pad. One embodiment of a mounting pad 200 is illustrated in FIG. 2 and will be described here with reference to FIG. 2.

The mounting pad 200 is a substantially rectangular plate with a flat top surface 210. The mounting pad 200 is preferably made of a metallic material such as steel or aluminum or a UV-stabilized plastic. A preferred embodiment of the mounting pad 200 is made from 3/16-inch thick, marine-grade aluminum. Aluminum is preferred, as it provides several advantages over other materials. It has the ability to provide protection against lightening strikes, thereby preventing damage to the enclosure and its contents. Additionally, marine-grade aluminum provides increased resistance to corrosion. In areas where lightening strikes are not a concern, UV-stabilized plastic can be used, thereby reducing costs of manufacture.

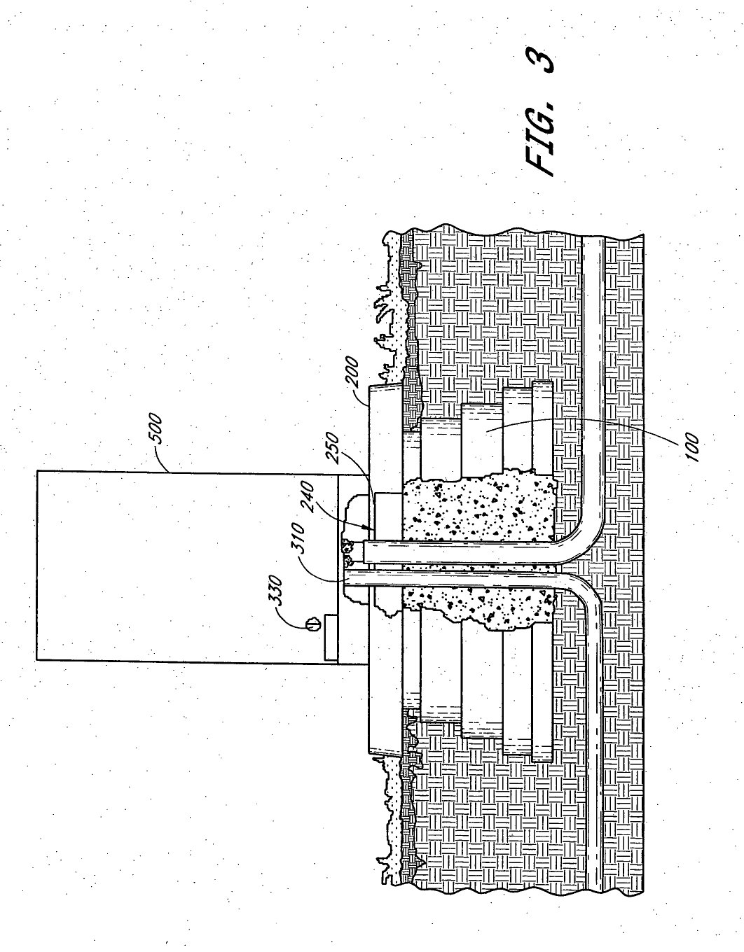

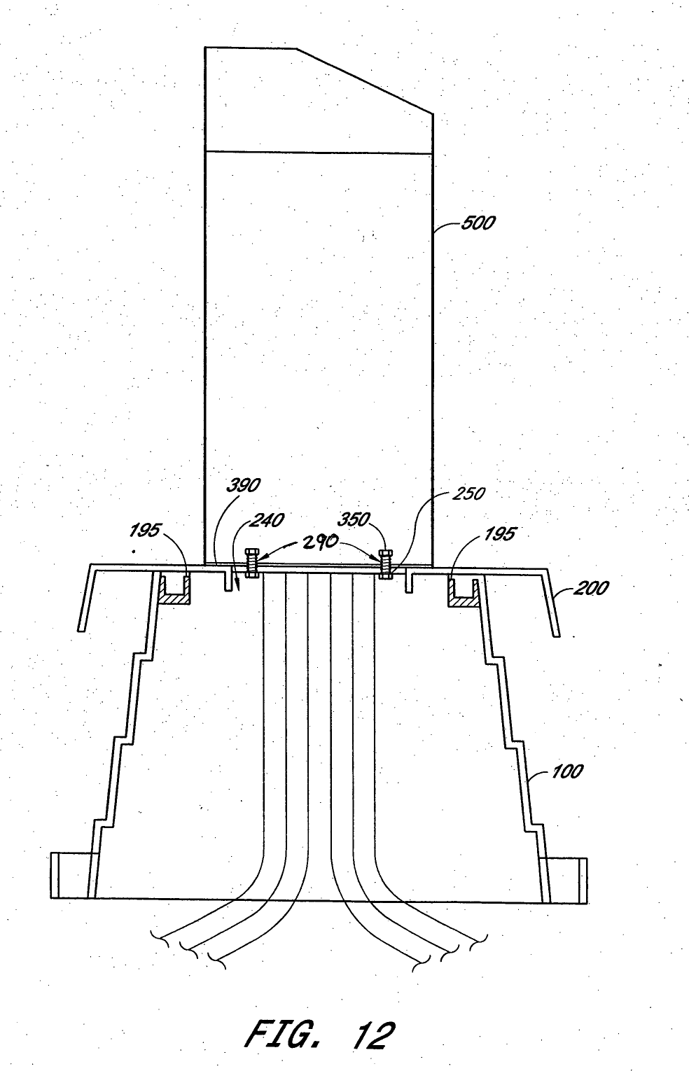

The mounting pad 200 is provided with an edging 220 that is formed perpendicular to the plane of the top surface 210. An opening 240 is provided near the center of the top surface 210 of the mounting pad 200. The opening 240 is sized so as to fit within the base of the enclosure 500 (see FIG. 12). Multiple openings can be provided, if desired, to accommodate multiple enclosures. In addition, the size and shape of the opening 240 may be varied to meet specific needs. The opening 240 in the mounting pad 200 should be sized to allow passage of the pipes, cables 310, field wires, and the like from the interior of the enclosure 500 into the ground below (see FIG. 3).

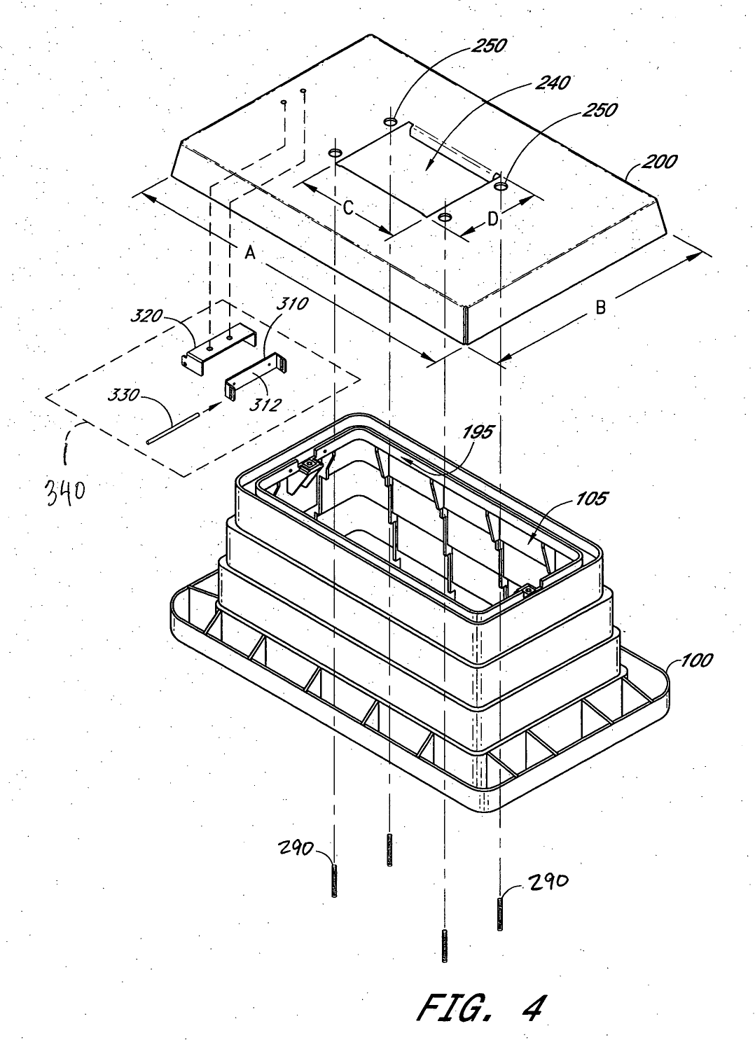

One or more holes 250, 260 are provided on the top surface 210 of the mounting pad 200. The holes 250 are provided around the opening 240 and are adapted to receive fasteners, such as bolts or screws, used to secure the enclosure to the mounting pad 200 and the support base 100. The holes 260 are also provided on the top surface 210 of the mounting pad 200 and are adapted for attaching a coupling structure (see FIG. 4). As is illustrated in FIG. 2, the holes 260 are located near to the edging 220 of the mounting pad 200. The holes 260 are preferably located near the top edge 120 of the support base 100 so that the entire mounting pad 200 tilts or pivots relative to the support base 100. As would be obvious to a person of ordinary skill in the art, the holes 260 may be located adjacent to any side of the mounting pad 200. Alternatively, the holes 260 may be located away from the edging 220 or at an angle relative to the edging 220. With the holes 260 and associated coupling structure located away from the edging 220, only a portion of the mounting pad 200 tilts or moves relative to the support base 100.

The coupling structure fixedly attaches the mounting pad 200 to the support base 100 while allowing limited movement of the mounting pad 200 relative to the support base 100. This limited movement can include, for example, allowing the mounting pad 200 to pivot or tilt relative to the support base 100. Pivoting or tilting the mounting pad 200 grants access to the interior of the support base 100. Alternatively, the mounting pad 200 may slide across the top surface of the support base 100 to thereby expose the interior of the support base 100, field wires, valves, or the like. The mounting pad 200 is then slid back across the support base 100 to inhibit access to the interior of the support base 100.

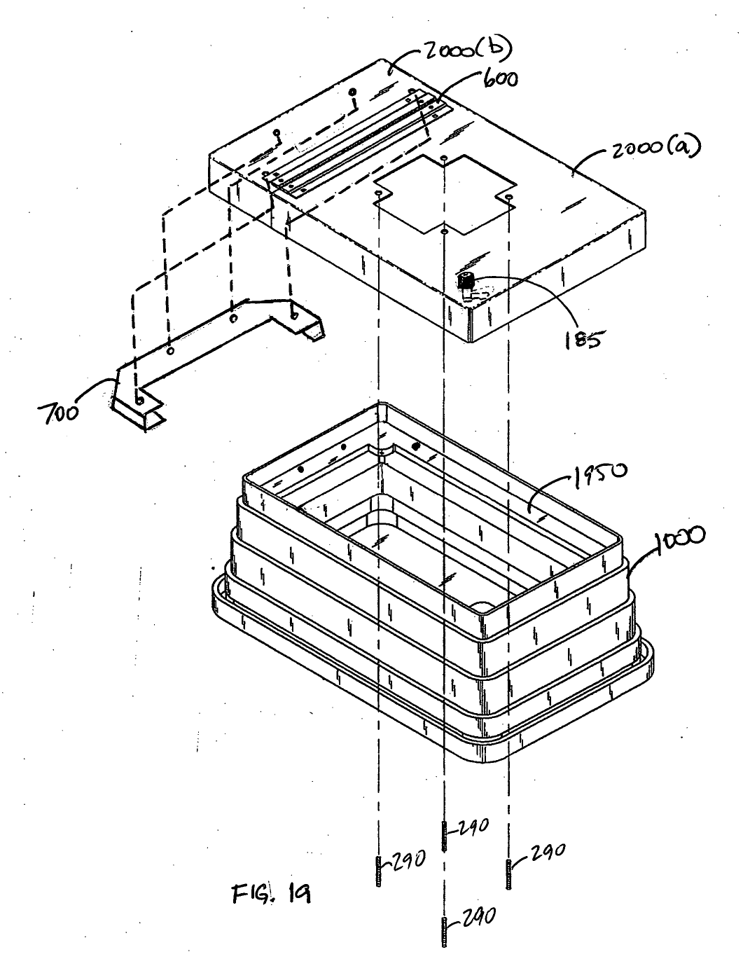

A locking mechanism 185 (see FIG. 19) may be provided between the mounting pad 200 and the support base 100 which can be unlocked so as to permit the mounting pad to pivot or tilt relative to the support base 100. The locking mechanism is preferably located on the side of the support base that is opposite to the coupling mechanism. The locking mechanism 185 may be a keyed, combination or other type of locking device.

Holes 260 are adapted to receive fasteners, such as bolts or screws, used to secure the coupling structure to the mounting pad 200. Preferably, the through holes 250, 260 are provided with rubber grommets (not shown) to keep the fasteners in place during the assembly and installation process.

FIGS. 3-6 illustrate the engagement of the support base 100, the mounting pad 200 and an enclosure 500. FIG. 3 is a partially cut-away view of a secure enclosure support system that includes the support base of FIG. 1 and the mounting pad of FIG. 2. Prior to installation, a hole roughly the shape of and slightly larger than the size of support base 100 is dug in the ground to accommodate the support base 100. The location of the hole can be determined by the location of the field wires, pipes, and cables 310 used, for example, to provide controls for a landscaping irrigation system. Once the hole is dug, the support base 100 is inserted into the hole. Preferably, approximately three inches of the support base 100 are left above ground to facilitate installation of the mounting pad 200. The inside of the support base 100 is then preferably filled with pea gravel or other filler to minimize rodent and moisture problems. Alternatively, the pea gravel can be added after the installation of the enclosure. This allows for the movement of the pipes and cables 310 during installation. Once the support base 100 is in position, dirt is backfilled and compacted around the outside of the support base 100. This secures the support base 100 in its location. The mounting pad 200 is then placed on top of the support base 100 with a coupling structure linking the mounting pad 200 to the support base 100.

FIG. 4 is an exploded view of the support base 100, the mounting pad 200, and a coupling structure 340. The coupling structure 340 is used to secure the support base 100 to the mounting pad 200 while allowing the mounting pad 200 to move relative to the support base 100. This movement may include, for example, tilting, pivoting, swiveling, sliding, and the like. As more clearly shown in FIG. 4, an embodiment of the coupling structure 340 comprises a receiver 310, a shackle 320, and a shaft 330. The receiver 310 and shackle 320 fixedly attach to the support base 100 and the mounting pad 200, respectively. The shaft 330 links the receiver 310 and the shackle 320 for rotation of the mounting pad 200 relative to the support base 100.

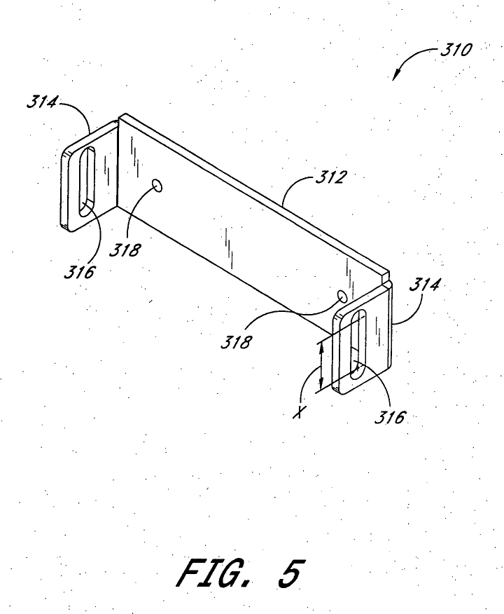

FIG. 5 is a perspective view of the receiver 310 component of the coupling structure 340 illustrated in FIG. 4. The receiver 310 comprises a body member or web 312 attached on either end to flanges 314 to form a generally U-shape. One or more holes 318 in the body member 312 are provided for fasteners to attach the receiver 310 to the support base 100. Alternatively, the fasteners may be permanently affixed to the body member 312. All mounting hardware is preferably made of stainless steel to prevent corrosion and rust.

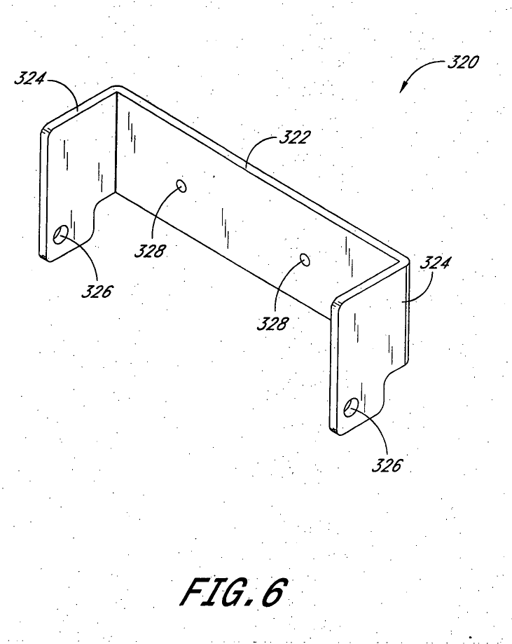

The flanges 314 included slotted holes 316 for receiving portions of the shaft 330. When assembled, the shaft 330 extends between the flanges 314, through the slotted holes 316, and past the outer surfaces of the flanges 314. In this way, the ends of the shaft 330 extend beyond the ends of the flanges 314 so as to engage with the shackle 320 (see FIG. 6). The length of the slotted holes 316 or dimension “X” can be shortened or lengthened to decrease or increase the degree of tilt of the mounting pad 200 relative to the support base 100.

As can be seen from FIG. 4, the body member 312 of the receiver 310 engages an interior ledge 195 of the support base 100. The interior ledge 195 preferably spans the length of at least one side of the support base 100 and is located near the top opening 105 of the support base 100. Preferably, the receiver 310 is installed with the top edges of the body member 312 and the flanges 314 located at or below the top edge 120 of the support base 100.

FIG. 6 is a perspective view of the shackle 320 component of the coupling structure 340 illustrated in FIG. 4. The shackle 320 comprises a body member or web 322 attached on either end to flanges 324 to form a generally U-shape. The flanges 324 of the shackle 320 are spaced farther apart than the flanges 314 of the receiver 310. In this way, the receiver 310 fits between the flanges 324 of the shackle 320 when assembled to form the coupling structure 340. Alternatively, the flanges 314 could be spaced farther apart than the flanges 324 to allow the shackle 320 to fit within the receiver 310.

One or more holes 328 in the body member 322 are provided for fasteners to attach the shackle 320 to the mounting pad 200. Alternatively, the fasteners may be permanently affixed to the body member 322. The flanges 324 included holes 326 for receiving the ends of the shaft 330. When assembled with the receiver 310, the shaft 330 extends from the holes 326 in the shackle 320 and through the slotted holes 316 in the receiver 310. The coupling structure 340 attaches to the interior ledge 195 of the support base 100 and to the surface of the mounting pad by fasteners extending through the holes 318, 328.

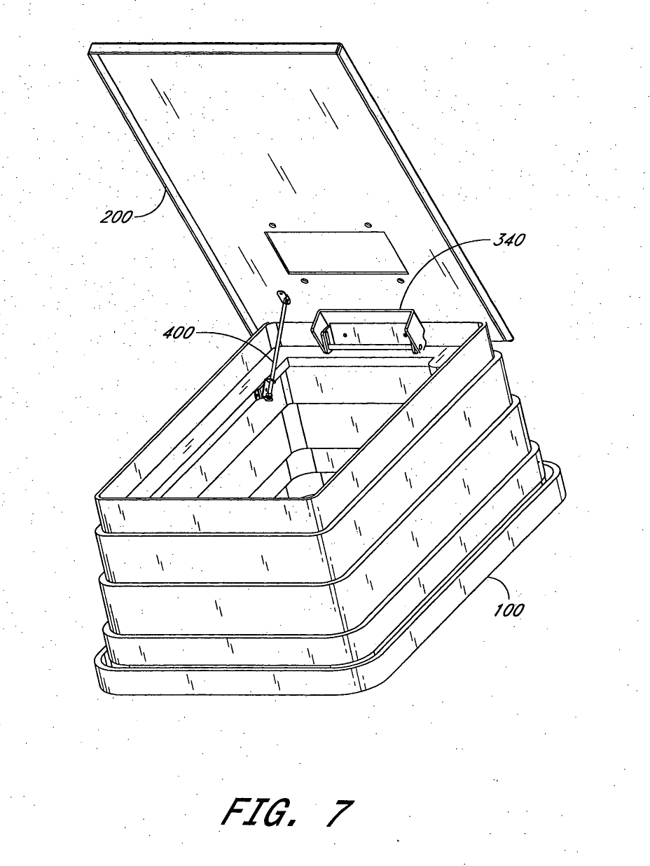

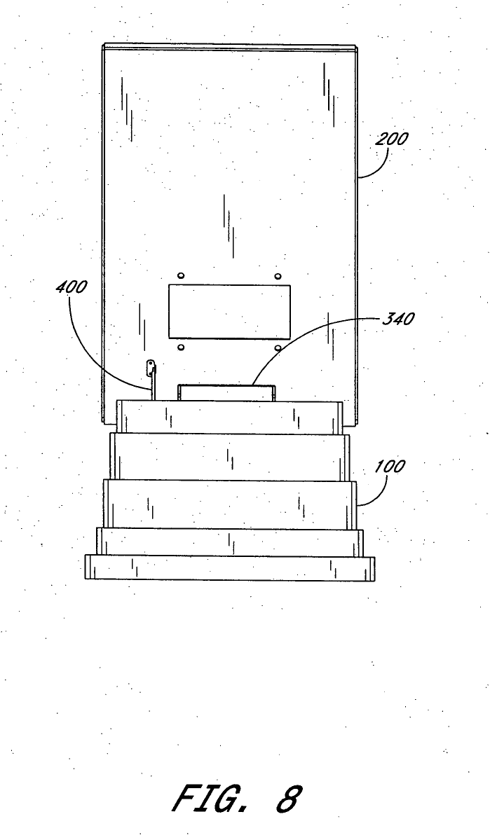

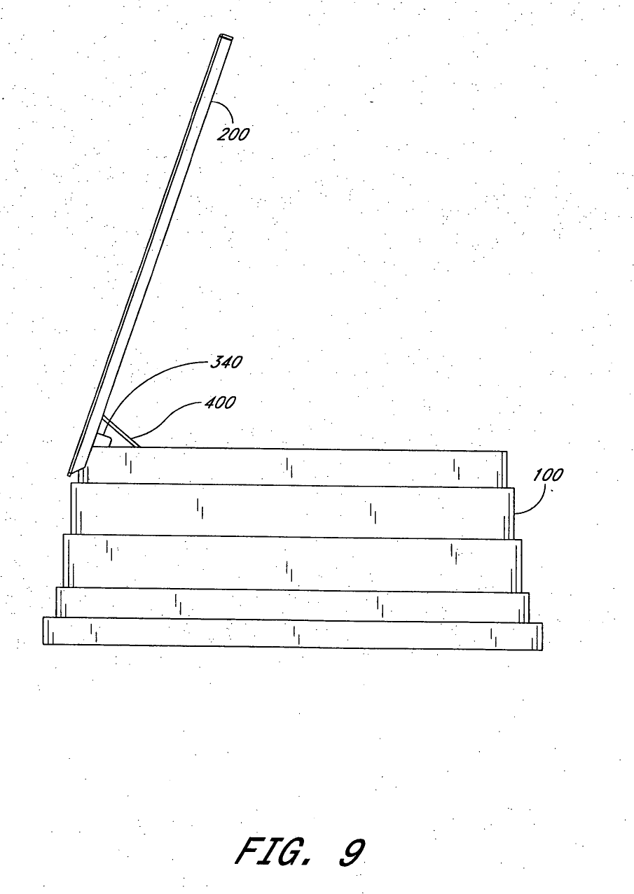

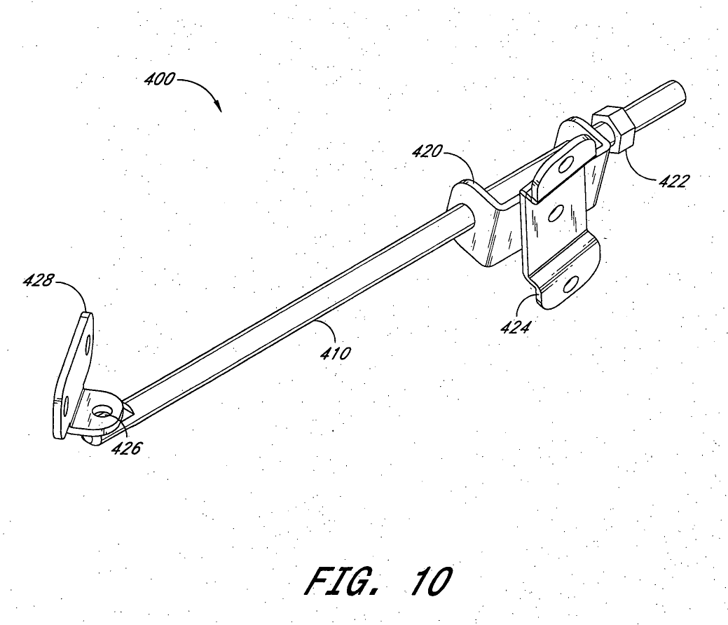

FIGS. 7-9 are views of the assembled coupling structure 340 attached to the support base 100 and the mounting pad 200. The coupling structure 340 is located near the intersection of the mounting pad 200 and the support base 100. FIGS. 8 and 9 are front and side views, respectively, of the support base 100 and the mounting pad 200. In FIGS. 7-9, the mounting pad 200 is in an open position to facilitate access within the support base 100. FIGS. 7-9 also illustrate a stop assembly 400 which is described in detail with reference to FIG. 10. The stop assembly 400 couples the support base 100 to the mounting pad 200 to limit or adjust the amount of travel or maximum tilt angle of the mounting pad 200 relative to the support base 100. While the use of the stop assembly 400 is preferred, it is not required to practice the invention.

FIG. 10 is an exploded view of the stop assembly 400 that can be used with the support base 100 and mounting pad 200. The stop assembly 400 serves as a fastener and as a guide. It serves as fasteners by holding the support base 100 and mounting pad 200 in an adjacent tilting relationship. The stop member 400 also serves as guides by limiting the sliding action to a back and forth linear extension and retraction. As shown in FIG. 10, a preferred exemplary embodiment of the stop member 400 comprises a slide member 420 and shaft member 410 which slidingly engage with each other. The slide member 420 is generally U-shaped and includes holes in opposing ends for receiving the shaft member 410. The shaft member 410 freely slides through the holes in the slide member 420.

A first end of the shaft member 410 receives an adjusting fastener or nut 422. The threads on the inside diameter of the nut 422 engage with threads on the outside diameter of the shaft member 410. Rotation of the nut 422 relative to the shaft member 410 shortens or lengthens the distance between the nut 422 and the second end of the shaft member 410 to thereby adjust the opening of the mounting pad 200. For example, shortening the distance between the nut 422 and the second end of the shaft member 410 decreases the maximum tilt of the mounting pad 200 relative to the support base 100.

The slide member 420 also has an opening in a web portion which can be used in conjunction with a connector and a bracket 424 to attach the slide member 420 to the base support 100 so that the slide member 420 may pivot about the connector. Similarly, the second end of the shaft member 410 has an opening 426 which can also be used in conjunction with a connector and a bracket 428 to attach the shaft member 410 to the mounting pad 200 so that the shaft member 410 may also pivot about the connector. Functionally, the stop assembly 400 can have either the first or second ends of the shaft member 410 attached to the mounting pad 200 or to the support base 100.

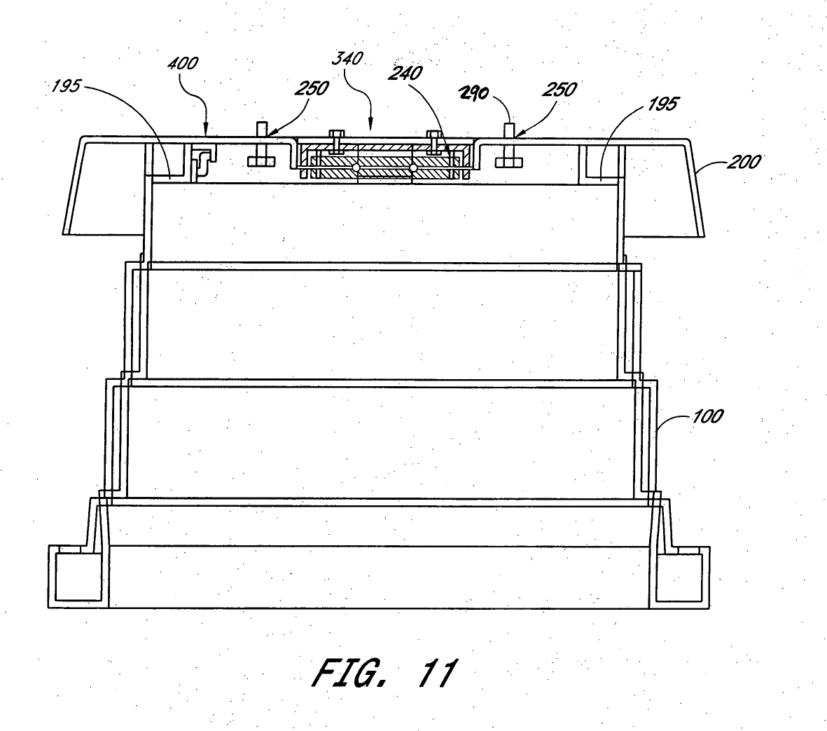

FIG. 11 is a cross-sectional view of the enclosure support system of FIG. 3 with the mounting pad 200 in a closed position relative to the support base 100. In this closed state, the body member or web 322 of the shackle 320 preferably lies parallel to the bottom surface of the mounting pad 200 with the body member or web 312 of the receiver 310 lying perpendicular to the body member 322.

As illustrated in FIG. 12, the enclosure 500 is then mounted on the mounting pad 200. The enclosure 500 is preferably a metal cabinet with a locking door 330 (see FIG. 3). The enclosure 500 is secured to the mounting pad 200 with the fasteners 290. The bolts 290 are inserted through the holes 250 in the mounting pad 200 and positioned in the corresponding holes provided in the base of 390 of the enclosure 500, extending into the interior of the enclosure 500. Nuts 350 are used to secure the bolts 290 in place. The mounting pad 200 and the enclosure 500 are thereby secured together. The fasteners 290 are advantageously located inside the enclosure 500, preventing vandals from removing them and accessing or removing the enclosure 500.

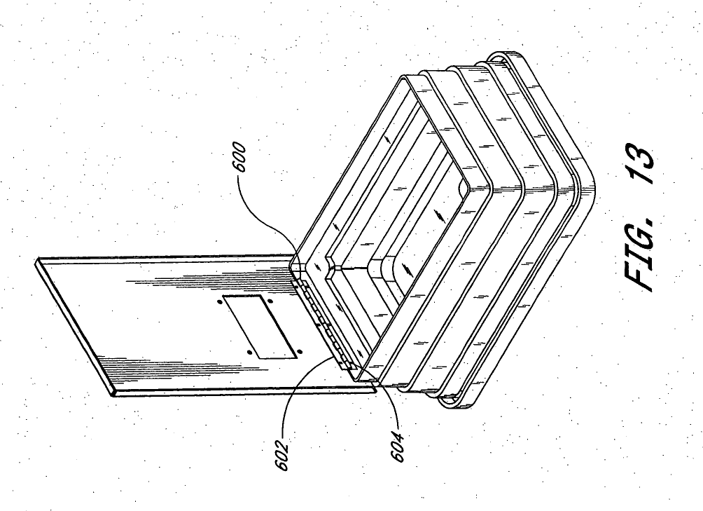

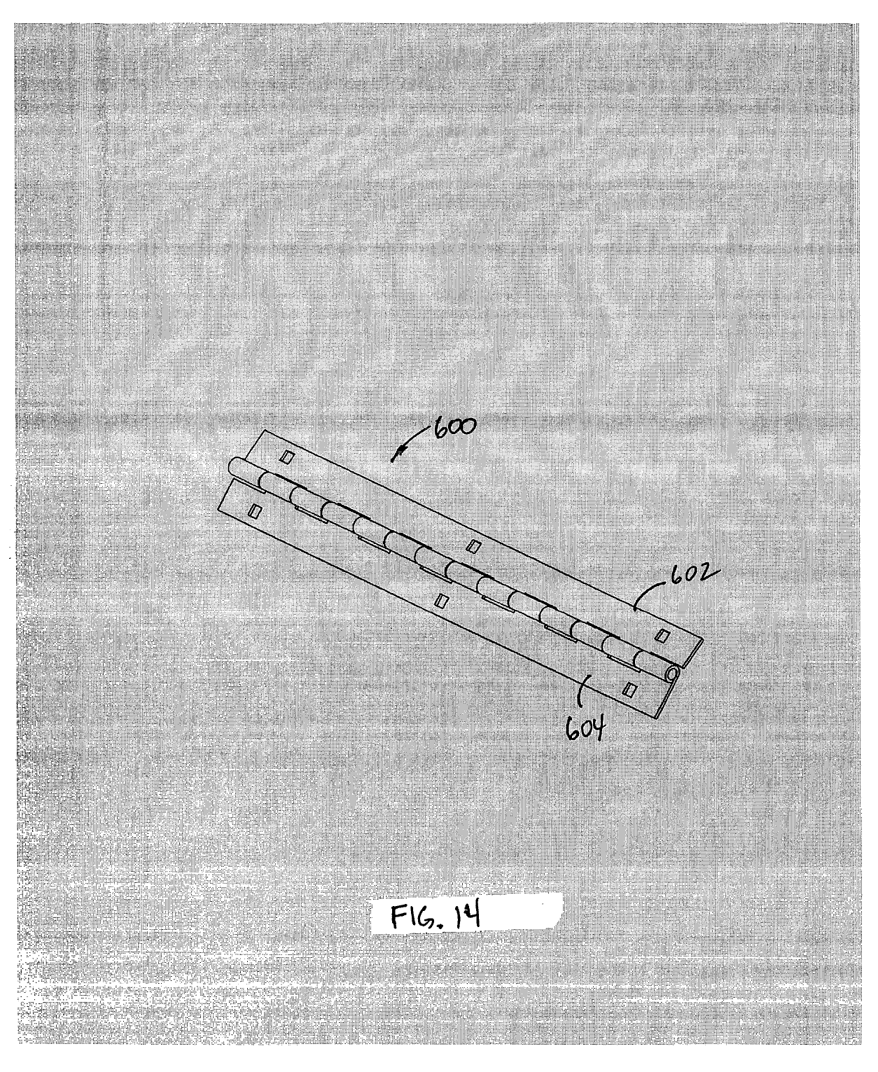

FIG. 13 is a perspective view of another embodiment of the support base 100 and mounting pad 200 having a coupling structure in the form of a hinge 600. FIG. 14 is a perspective view of the hinge from FIG. 13. The hinge 600 can be a common barrel-type hinge formed from two leaves 602, 604. The leaves 602, 604 are generally rectangular, although any shape is possible. The two leaves 602, 604 include formed apertures or holes whereby the leaves are individually mounted to the mounting pad 200 and the support base 100. The holes are of suitable construction and relative placement to mount the mounting pad or support base 100, and are dependent on the type of installation (e.g. size, weight, profile, loads, etc.).

The leaves 602, 604 of the barrel hinge have interfitting, axially aligned knuckles along their opposed marginal edges for receiving a pin there through. The pin allows the leaves 602, 604 to swing with respect to the other. The axially aligned, spaced knuckles may vary in number and are adapted to receive there between or adjacent thereto a knuckle from the opposed edge of the other leaf. The axially aligned knuckles receive the end of the pin opposite to the head. The head keeps the pin from sliding out through the knuckles of the leaves. A pin or nut can be used to fix the end of the pin opposite to the head. The pin should be at least as long as the axially aligned knuckles.

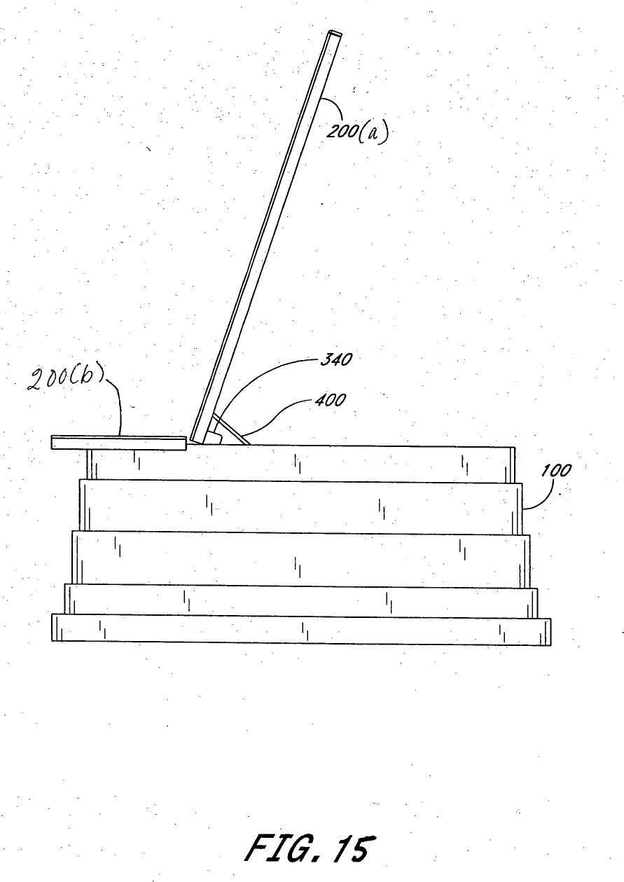

As shown in FIG. 15, an embodiment of the mounting pad comprises portions 200(a), 200(b). The mounting pad portion 200(a) is similar to the mounting pad 200 described with reference to FIG. 2 except that the mounting pad 200(a) is shorter than the length of the support base 100. The region of the support base 100 not covered by the mounting pad portion 200(a) is covered by mounting pad portion 200(b). Mounting pad portion 200(b) can be fixedly attached to the support base 100. In this way, only a portion of the mounting pad tilts or pivots when accessing the field wires, valves, or the like in the interior of the support base 100.

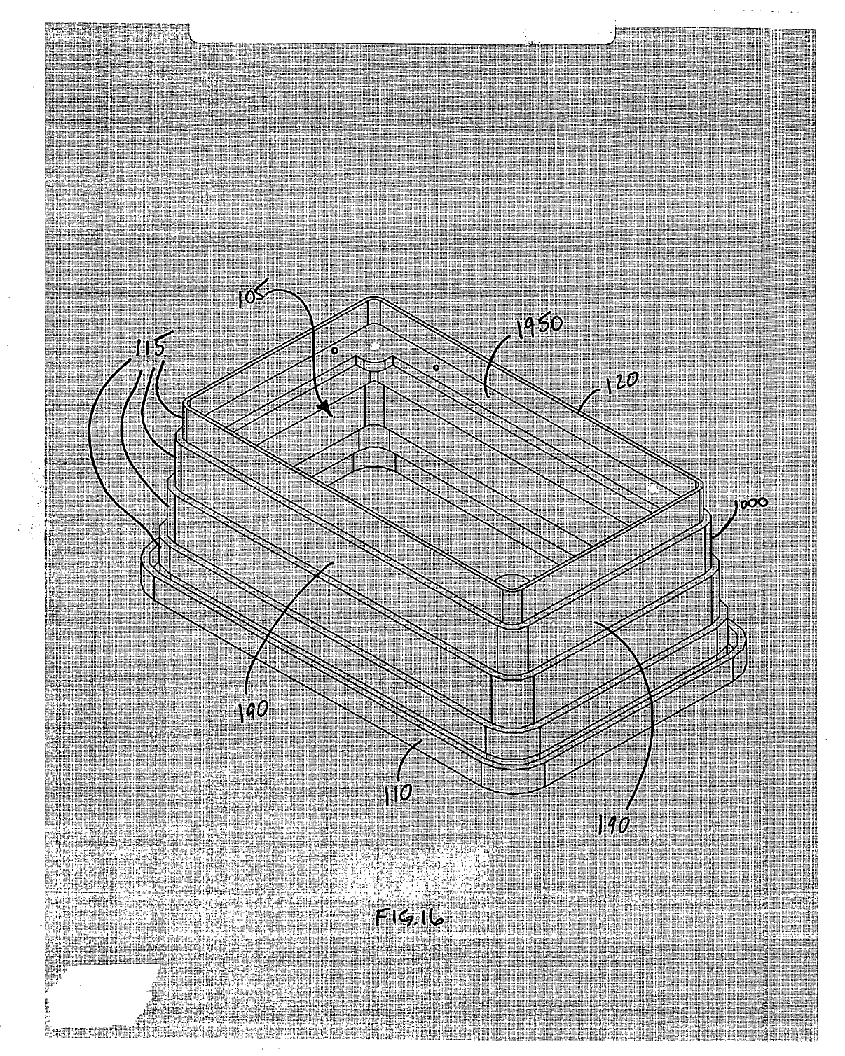

FIGS. 16-23 illustrate another embodiment of a support base 1000, a mounting pad 2000 and a coupling structure 600. The support base 1000 is similar to the support base 100 described with reference to FIG. 1 except that the ledge 1950 is configured to support an anchor member between a top surface of the ledge and the mounting pad. The mounting pad portions 2000(a), 2000(b) are similar to the mounting pad portions 200(a), 200(b) described with reference to FIG. 15 except that the mounting pad portions are coupled together with a different coupling structure than was illustrated in FIG. 15. However, the various features from the embodiments of the coupling structure, support base, and mounting pad disclosed with regard to specific embodiments may be interchanged and combined to modify or form additional embodiments of the enclosure that are still within the scope of the disclosure.

FIG. 16 illustrates another embodiment of a support base 1000 for use in a system for supporting and installing enclosures. As illustrated, the support base 1000 is made of several tiers of rectangular-shaped frames 115, stacked upon one another. The size of the frames 115 gradually decreases from bottom to top of the support base 1000. The support base 1000 is preferably made of a heavy-duty plastic, but may also be formed of fiberglass, metal or any other suitable material.

The support base 1000 preferably has an open bottom and an open top 105 and is hollow throughout. The support base 1000 has four side surfaces 190 forming the sides of a rectangular box, and a base 110. The base 110 is the largest of the tiers and forms a relatively large rectangular shape that forms the bottom of the four side surfaces 190 of the rectangular box. The support base 1000 is designed to support the mounting pad and the enclosure.

As illustrated in FIG. 16, the first frame 115 is located partially above the base 110. The first frame 115 has a rectangular footprint that is smaller than that of the base 110. Thus, the footprint of the first frame 115 is a rectangle located inside another rectangle representing the footprint of the base layer 110. Similarly, a second, third, and fourth frames 115 are provided above the first frame 115, each having a successively smaller rectangular footprint. Each frame 115 has its rectangular footprint within the rectangular footprint of the preceding frame 115. The height of each of the frames may be designed to provide a desired height for the support base 1000. The height is selected to provide sufficient stability when the support base 1000 is installed. This configuration provides the support base 1000 with a somewhat conical profile. According to the embodiment illustrated in FIG. 16, each side surface 190 is provided with four vertical portions 115. However, it is understood that any number of vertical portions 115 can be used to form the side surfaces 190. Alternatively, the side surfaces 190 can be continuous smooth surfaces forming a truncated pyramidal shape. Additionally, it is understood that the support base 1000 need not be of a rectangular shape; various shapes can be used, including but not limited to any polygonal cone or a purely circular cone.

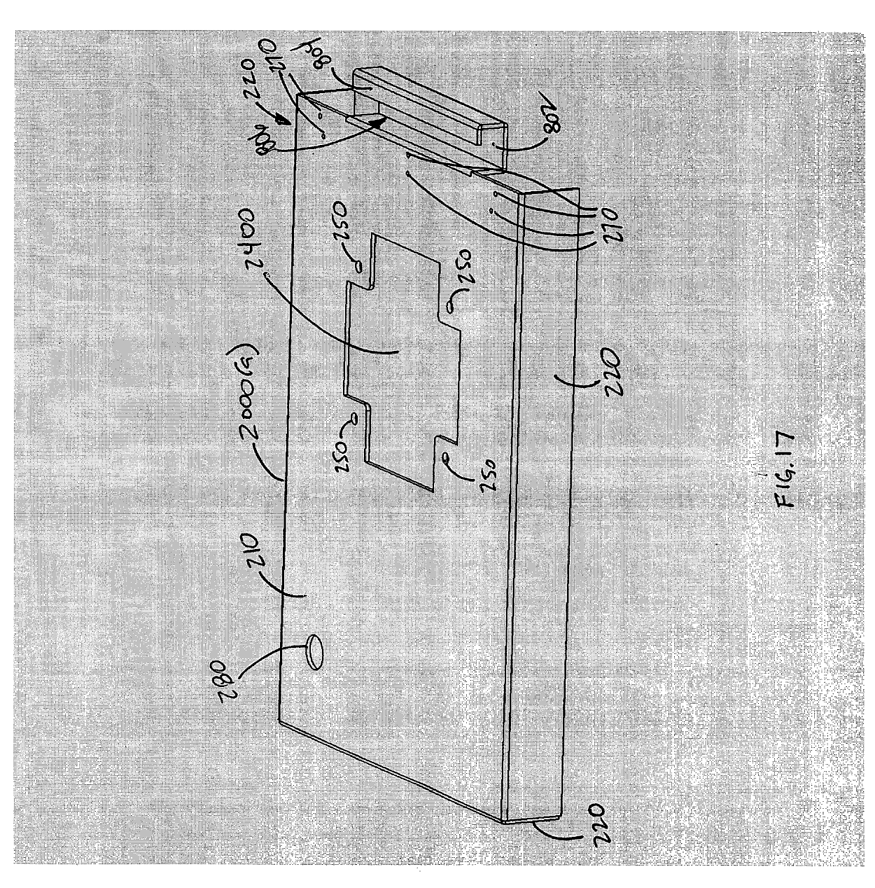

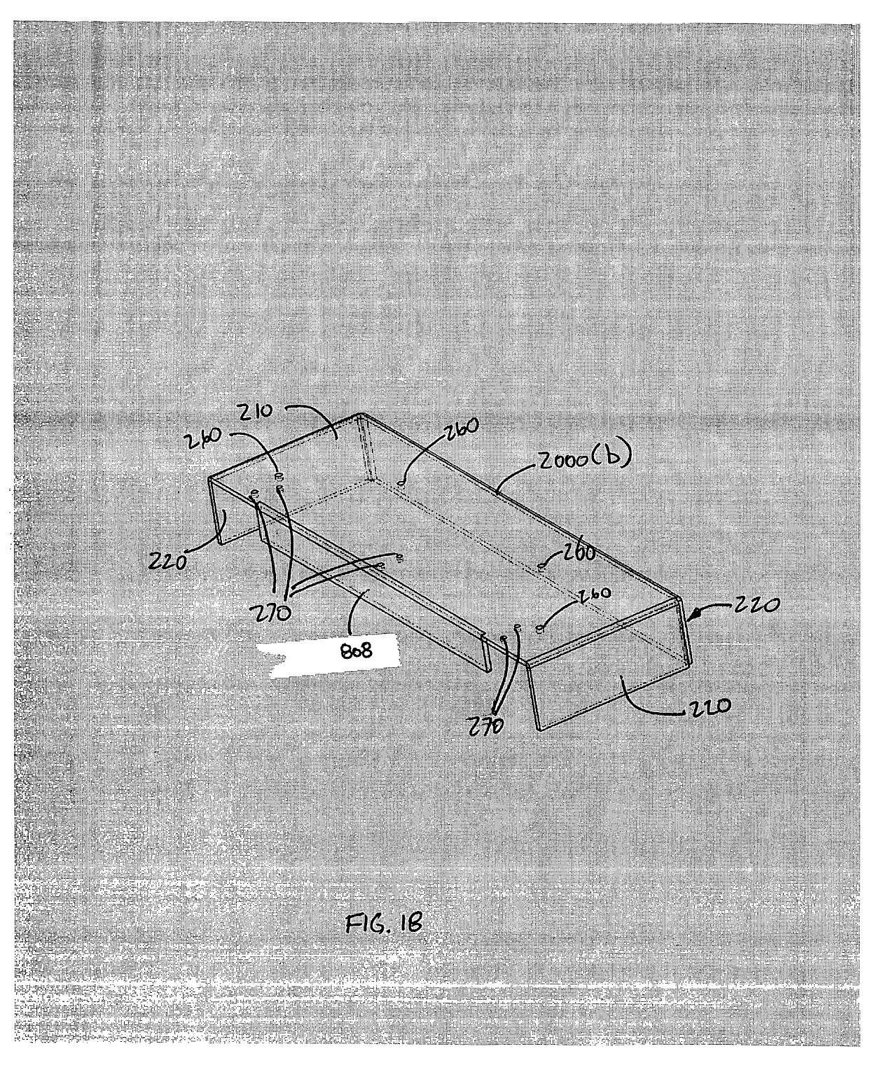

A ledge 1950 is located on the interior surface of the support base 1000, near the top edge 120. The top edge 120 is preferably of a substantially rectangular shape. The top edge 120 of the uppermost vertical portion 115 serves as a resting surface for a multi-piece mounting pad. One embodiment of the multi-piece mounting pad 2000(a), 2000(b) is illustrated in FIGS. 17 and 18.

The multi-piece mounting pad comprises portion 2000(b) which is fixedly attached to the support base 1000 by anchor member 700 (see FIG. 19). Referring to FIGS. 17 and 19, mounting pad portion 2000(a) is coupled to mounting pad portion 2000(b) and opens and closes with respect to the support base 1000. A coupling structure, in the form of a hinge 600 for example, attaches the mounting pad portion 2000(a) to the mounting pad portion 2000(b). Additional coupling structure may also be utilized as is described below.

Mounting pad portions 2000(a), 2000(b) each are a substantially rectangular plate with a flat top surface 210. The mounting pad portions 2000(a), 2000(b) are preferably made of a metallic material such as steel or aluminum or a UV-stabilized plastic. A preferred embodiment of the mounting pad portions 2000(a), 2000(b) is made from 3/16-inch thick, marine-grade aluminum. Aluminum is preferred, as it provides several advantages over other materials. It has the ability to provide protection against lightening strikes, thereby preventing damage to the enclosure and its contents. Additionally, marine-grade aluminum provides increased resistance to corrosion. In areas where lightening strikes are not a concern, UV-stabilized plastic can be used, thereby reducing costs of manufacture.

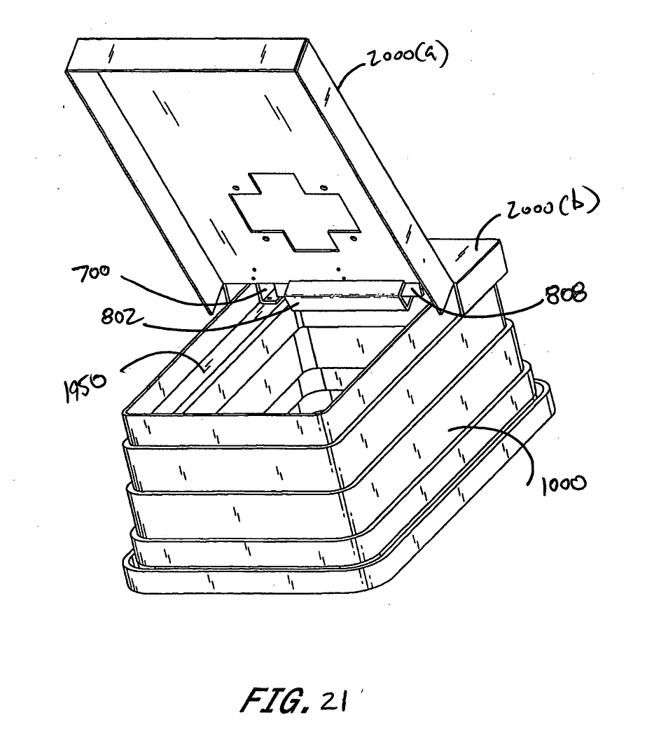

The mounting pad portions 2000(a), 2000(b) are provided with an edging 220 that is formed perpendicular to the plane of the top surface 210. The edging 220 extends around three sides of the mounting pad portions 2000(a), 2000(b). However, it is to be understood that the edging 220 may extend around more or less of the sides as well as only extending around portions of one or more of the sides. For ease of description, the fourth sides of the mounting pad portions 2000(a), 2000(b) are located adjacent to each other when the mounting pad portions are installed onto the support base 1000 (see FIG. 21). As explained below, the fourth sides of the mounting pad portions 2000(a), 2000(b) interact with each other to further couple the mounting pad portions 2000(a), 2000(b).

As illustrated in FIG. 17, the fourth side of mounting pad portion 2000(a) includes channel 802. The channel 802 has a longitudinal axis which is parallel to the rotational or pivot axis of the mounting pad 2000(a) relative to the mounting pad 2000(b). The channel 802 further includes an opening 806 and lip 804 along the longitudinal axis. The opening 806 is located along an upper surface of the channel 802 and is partially closed by the lip 804. One end of the channel 802 is open on the near side in FIG. 17 while the other end is closed on the far side. Closing one end of the channel 802 inhibits longitudinal motion of the mounting pad 2000(b) when inserted into the channel 802 and may further provide additional structural support to the channel 802 and the lip 804.

An opening 2400 is provided through the top surface 210 of the mounting pad portion 2000(a). The opening 2400 is sized so as to fit within the base of the enclosure 500 (see FIG. 12). Multiple openings can be provided, if desired, to accommodate multiple enclosures. In addition, the size and shape of the opening 2400 may be varied to meet specific needs. The opening 2400 in the mounting pad portion 2000(a) should be sized to allow passage of the pipes, cables 310, field wires, and the like from the interior of the enclosure 500 into the ground below (see FIG. 3).

The mounting pad portion 2000(a) includes one or more holes 250, 270 on the top surface 210. The holes 250 are provided around the opening 2400 and are adapted to receive fasteners, such as bolts or screws, used to secure the enclosure to the mounting pad 2000(a). The holes 270 are provided near the channel 802 and are adapted to receive fasteners, such as bolts or screws, used to secure the coupling structure 600 to the mounting pad 2000(a).

A locking mechanism 185 may be provided between the mounting pad 2000(a) and the support base 1000 which can be unlocked so as to permit the mounting pad to pivot or tilt relative to the support base 1000. For example, hole 280 can be configured to receive the locking mechanism. The locking mechanism is preferably located on the side of the support base 1000 that is opposite to the coupling mechanism 700. The locking mechanism 185 may be a keyed, combination or other type of locking device.

As illustrated in FIG. 18, the fourth side of mounting pad portion 2000(b) includes flap 808. Flap 808 extends perpendicular to the plane of the top surface 210. The flap 808 is configured to extend through the opening 806 and into the channel 802 of the mounting pad portion 2000(a) when the mounting pad portions 2000(a), 2000(b) are attached to the support base 1000. To access the inside of the support base 1000 after the mounting pads are attached thereto, the mounting pad 2000(a) can be pivoted about the rotational axis until an inside surface of the lip 804 abuts against an inside surface of the flap 808 and inhibits additional rotational motion of the mounting pad 2000(a).

The mounting pad portion 2000(b) includes one or more holes 260, 270 on the top surface 210. The holes 260 are located near to the edging 220 of the mounting pad 2000(b). The holes 260 are preferably located near the top edge 120 and in line with the ledge 1950 (see FIG. 16). The holes 260 are adapted to receive fasteners, such as bolts or screws, used to secure the mounting pad 2000(b) to an anchor member 700 (see FIG. 19). As will be described below, the anchor member 700 is further secured to the support base 1000. The holes 270 are provided near the flap 808 and are adapted to receive fasteners, such as bolts or screws, used to secure the coupling structure 600 to the mounting pad 2000(b).

Preferably, the through holes 250, 260, 270 in the mounting pads 2000(a), 2000(b) are provided with rubber grommets (not shown) to keep the fasteners in place during the assembly and installation process.

The anchor member 700 fixedly attaches between the mounting pad 2000(b) and the support base 1000 (see FIG. 19). In contrast, the coupling structure 600 alone or in combination with the flap 808 and channel 802 allows limited movement of the mounting pad portion 2000(a) relative to the mounting pad portion 2000(b). This limited movement can include, for example, allowing the mounting pad 2000(a) to pivot or tilt relative to the support base 1000. Pivoting or tilting the mounting pad 2000(a) grants access to the interior of the support base 1000. Alternatively, the mounting pad 2000(a) may slide across the top surface of the support base 1000 to thereby expose the interior of the support base 1000, field wires, valves, or the like. The mounting pad 2000(a) is then slid back across the support base 1000 to inhibit access to the interior of the support base 1000.

FIG. 19 is an exploded view of the support base 1000, the mounting pad portions 2000(a), 2000(b), the anchor member 700, and a coupling structure 600. The anchor member 700 is used to secure the support base 1000 to the mounting pad portion 2000(b). The coupling structure 600 alone or in combination with the flap 808 and channel 802 allows limited movement of the mounting pad portion 2000(a) relative to the mounting pad portion 2000(b).

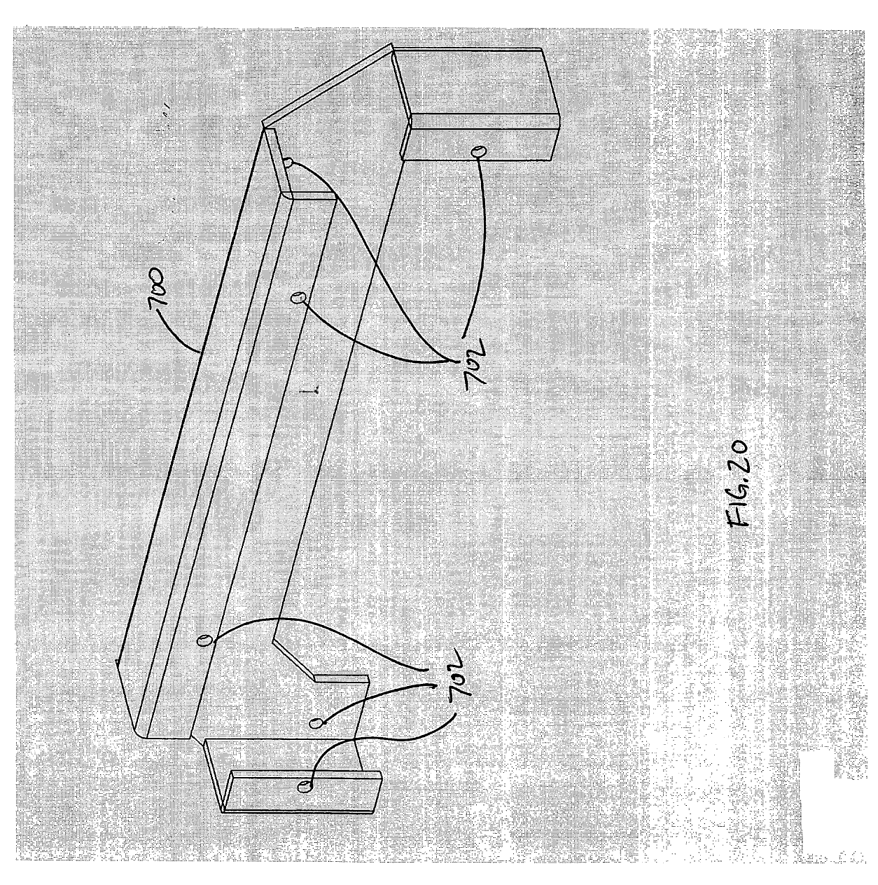

An embodiment of the anchor member 700 is more clearly shown in FIG. 20. The anchor member 700 includes holes 702 for receiving fasteners or the like for fixedly attaching the anchoring member 700 to the support base 1000 and to the mounting pad portion 2000(b). The holes 702 are preferably aligned with the holes 260, or vice versa, so that fasteners can pass between the mounting pad portion 2000(b) and the anchor member 700. The holes 260, 702 may be further aligned with holes located in the ledge 1950 of the support base 1000 to allow the fasteners to engage with the support base 1000.

FIGS. 21 through 23 are views of the assembled coupling structure 600 and anchor member 700 attached to the support base 1000 and the mounting pad portions 2000(a), 2000(b). The coupling structure 600, flap 808, and channel 802 are located near the intersection of the mounting pad portions 2000(a), 2000(b). As can be seen from FIG. 21, the flap 808 of the mounting pad portion 2000(b) engages the channel 802 of the mounting pad portion 2000(a) to limit rotational movement of the mounting pad 2000(a) relative to the mounting pad portion 2000(b). The channel 802 configuration may further allow the mounting pad portion 2000(a) to lock in an open position. In this locked open position, the inner surface of the lip 804 rests against an inner surface of the flap 808. In this way, the travel or maximum tilt angle of the mounting pad 2000(a) relative to the support base 1000 can be limited. While this feature is preferred, it is not required to practice the invention.

FIG. 21 further illustrates the anchor member 700 fixedly attached to the ledge 1950 of the mounting base 1000. The interior ledge 1950 preferably spans the length of at least one side of the support base 1000 and is located near the top opening 105 of the support base 1000. Preferably, the anchor member 700 is installed with the top edges of the anchor member 700 located at or below the top edge 120 of the support base 1000.

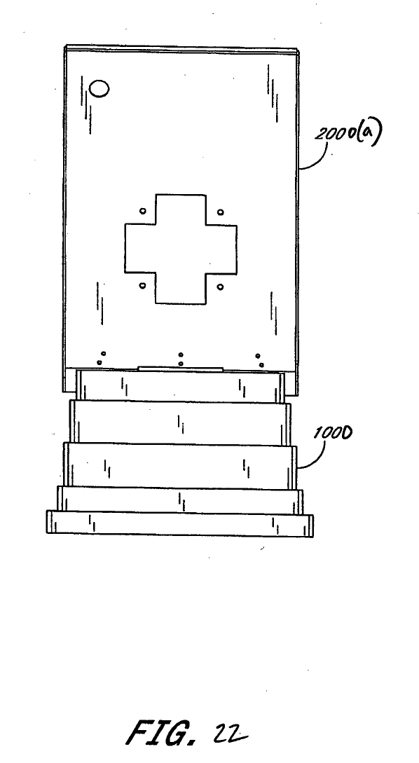

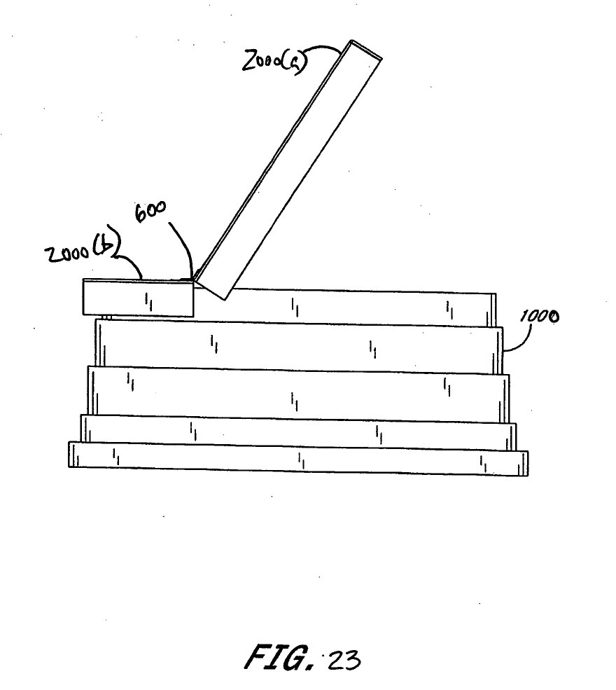

FIGS. 22 and 23 are front and side views, respectively, of the support base 1000 and the mounting pads 2000(a), 2000(b). In FIGS. 22 and 23, the mounting pad 2000(a) is in an open position to facilitate access within the support base 1000.

Embodiments of the support bases and the mounting pads may be designed to support two or more enclosures. For example, the mounting pad can be provided with two openings each with a set of through holes.

Advantageously, the mounting pad can be provided in a variety of colors adapted to satisfy the varying needs. For example, the mounting pad may be provided in green to match the color of a grassy landscape. Other colors may be used, for example, with desert landscapes.

Thus, the invention provides a secure installation of an enclosure without the need for special preparation of the ground for pouring of concrete. Additionally, the mounting pad is easily manufactured to accommodate a wide variety of support bases and enclosures. The installation is made secure by preventing unauthorized access to the mounting hardware. Further, the use of the coupling structure facilities maintenance access to the interior of the support base.

While the above detailed description has shown, described, and pointed out novel features of the invention as applied to various embodiments, it will be understood that various omissions, substitutions, and changes in the form and details of the device illustrated may be made by those skilled in the art without departing from the spirit of the invention.

What is claimed is:

1. A mounting assembly for enclosing and accessing electronics or wires, comprising:
a support base having a bottom, a top and a substantially hollow interior, the interior configured to contain at least a portion of the electronics or wires;
a mounting pad resting on the top of the support base, the mounting pad having an opening in a substantially flat top surface; and
a coupling structure attached to the mounting pad, the coupling structure configured to allow the mounting pad to move between an open position and a closed position relative to the support base, wherein the interior is accessible when the mounting pad is in the open position and is inaccessible when the mounting pad is in the closed position.

2. The assembly of claim 1, wherein the coupling structure comprises:
a receiver attached to the support base;
a shackle attached to the mounting pad; and
a shaft member configured to link the receiver and the shackle so as to allow the mounting pad and the support base to rotate relative to one another.

3. The assembly of claim 2, wherein the shackle and the receiver are generally U-shaped.

4. The assembly of claim 1, wherein the coupling structure comprises a hinge.

5. The assembly of claim 1, wherein the mounting pad pivots with respect to the support base.

6. The assembly of claim 1, wherein the mounting pad slides with respect to the support base.

7. The assembly of claim 1, wherein the mounting pad tilts with respect to the support base.

8. The assembly of claim 1 further comprising a stop assembly attached to the support base and the mounting pad and configured to limit the movement of the mounting pad relative to the support base.

9. The assembly of claim 1, wherein the support base has a rectangular footprint.

10. The assembly of claim 1, wherein the support base is made of plastic.

11. The assembly of claim 1, wherein the mounting pad is made of metal.

12. The assembly of claim 1, wherein the mounting pad is made of marine-grade aluminum.

13. The assembly of claim 1, wherein the mounting pad is made of UV-stabilized plastic.

14. The assembly of claim 1, wherein the mounting pad is a rectangular plate.

15. The assembly of claim 1, further comprising strengthening flanges located on the support base.

16. The assembly of claim 1, wherein the mounting pad rests on a top edge of the support base when the mounting pad is in the closed position.

17. The assembly of claim 1, wherein the support base further comprises a ledge located on an upper interior surface, wherein the coupling structure is secured to the ledge.

18. The assembly of claim 1, wherein the mounting pad has a plurality of openings in its top surface.

19. The assembly of claim 1, further comprising a locking device for locking the support pad to the support base.

20. The assembly of claim 1, wherein the mounting pad comprises at least a first portion and a second portion, and wherein the second portion is fixedly attached relative to the support base and is further attached to the coupling structure, and wherein the first portion is attached to the coupling structure so as to allow the first portion to move between the open position and the closed position relative to the second portion.

21. The assembly of claim 20, further comprising an anchor member attached to the second portion of the mounting pad and to the support base.

22. The assembly of claim 21, wherein the locking device is located in the support pad and locks to the support base.

23. The assembly of claim 21, wherein the locking device is located in the support base and locks to the support pad.

24. A method of securely installing an enclosure mounting pad on an area of ground, comprising:
digging a hole in the ground to accommodate a support base therein;
inserting the support base in the hole, the support base having a top, a bottom and an interior;
placing a mounting pad on top of the support base, the mounting pad having an opening in a top surface; and
attaching a coupling structure to the mounting pad so as to access the interior when the mounting pad is tilted relative to the support base.

25. The method of claim 24, further comprising:
mounting an enclosure on top of the mounting pad, the enclosure being secured by a fastener, wherein the fastener is located in an interior of the enclosure.

26. The method of claim 24, further comprising:
filling the interior of the support base with filler.

27. The method of claim 24, further comprising:
backfilling the hole after inserting the support base.

28. The method of claim 24, wherein the mounting pad comprises at least a first portion and a second portion, and wherein placing the mounting pad on top of the support base and attaching the coupling structure to the mounting pad comprises:
fixedly attaching the second portion of the mounting pad to the support base;
attaching the second portion to the coupling structure; and
attaching the first portion to the coupling structure so as to allow the first portion to move between an open position and a closed position relative to the second portion.

29. An enclosure assembly, comprising:
a support base having a bottom, a top and a hollow interior;
a mounting pad resting on the top of the support base, the mounting pad having an opening in a top surface;
a coupling structure attached to the mounting pad; and
an enclosure having a base mounted on the top surface of the mounting pad, the enclosure having an opening in the base sized so as to surround the opening in the top surface of the mounting pad.

30. The assembly of claim 29, wherein the coupling structure comprises:
a receiver attached to the support base;
a shackle attached to the mounting pad; and
a shaft member configured to link the receiver and the shackle so as to allow the mounting pad and the support base to rotate relative to one another.

31. The assembly of claim 29, wherein the coupling structure comprises a hinge.

32. The assembly of claim 29 further comprising a stop assembly attached to the support base and the mounting pad, and configured to limit the rotation of the mounting pad relative to the support base.

33. The assembly of claim 29, wherein the enclosure is a metal cabinet.

34. The assembly of claim 29, wherein the mounting pad comprises at least a first portion and a second portion, and wherein the second portion is fixedly attached relative to the support base and is further attached to the coupling structure, and wherein the first portion is attached to the coupling structure so as to allow the first portion to move between the open position and the closed position relative to the second portion.

35. The assembly of claim 34, further comprising an anchor member attached to the second portion of the mounting pad and to the support base.

36. The assembly of claim 29, further comprising a locking device for locking the support pad to the support base.

37. The assembly of claim 36, wherein the locking device is located in the support pad and locks to the support base.

38. The assembly of claim 36, wherein the locking device is located in the support base and locks to the support pad.
